(19) United States
(12) Patent Application Publication
(10) Pub. No.: US 2013/0192661 A1
(43) Pub. Date: Aug. 1, 2013

(54) LARGE AREA CONCENTRATOR LENS STRUCTURE AND METHOD

(71) Applicant: Solaria Corporation, Fremont, CA (US)

(72) Inventors: Kevin R. GIBSON, Redwood City, CA (US); Abhay Maheshwari, Monte Sereno, CA (US)

(73) Assignee: Solaria Corporation, Fremont, CA (US)

(21) Appl. No.: 13/744,368

(22) Filed: Jan. 17, 2013

Related U.S. Application Data
(63) Continuation of application No. 12/709,438, filed on Feb. 19, 2010, now abandoned.
(60) Provisional application No. 61/154,357, filed on Feb. 20, 2009.

(51) Int. Cl. H01L 31/052; H01L 31/18

(52) U.S. Cl. CPC H01L 31/0524; H01L 31/18
USPC 136/246; 438/65

(57) ABSTRACT

A solar module includes a substrate member, a plurality of photovoltaic strips arranged in an array configuration overlying the substrate member, and a concentrator structure comprising extruded glass material operably coupled to the plurality of photovoltaic strips. A plurality of elongated convex regions are configured within the concentrator structure. The plurality of elongated convex regions are respectively coupled to the plurality of photovoltaic strips. Each of the plurality of elongated convex regions includes a length and a convex surface region characterized by a radius of curvature, each of the elongated convex regions being configured to have a magnification ranging from about 1.5 to about 5. A coating material rendering the glass self-cleaning overlies the plurality of elongated convex regions.

### CROSS-REFERENCES TO RELATED APPLICATIONS

This application claims priority to U.S. patent application Ser. No. 12/709,438, filed Feb. 19, 2010, which claims priority to U.S. Patent Application No. 61/154,357, filed Feb. 20, 2009 for “Large Area Concentrator Lens Structure and Method” (inventors Kevin R. Gibson and Abhay Maheshwari), the entire disclosure of which is incorporated by reference for all purposes.

This application describes subject matter related to that disclosed in copending, commonly owned U.S. patent application Ser. No. 12/687,862 filed Jan. 14, 2010 for “Solar Cell Concentrator Structure Including a Plurality of Glass Concentrator Elements With a Notch Design”, the entire disclosure of which is incorporated by reference for all purposes.

### BACKGROUND OF THE INVENTION

The present invention relates generally to solar energy techniques, and in particular to a method and a structure for a resulting solar module. Merely by way of example, the embodiments of the invention have been applied to solar panels, but it would be recognized that the invention has a much broader range of applicability.

As the population of the world has increased, industrial expansion has led to a corresponding increased consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

In addition to oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many desirable characteristics; it is renewable, clean, abundant, and often widespread. Certain technologies developed often capture solar energy, concentrate it, store it, and convert it into other useful forms of energy.

Solar panels have been developed to convert sunlight into energy. For example, solar thermal panels are used to convert electromagnetic radiation from the sun into thermal energy for heating homes, running certain industrial processes, or driving high grade turbines to generate electricity. As another example, solar photovoltaic panels are used to convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successfully for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of costly photovoltaic silicon bearing wafer materials, which are often difficult to manufacture efficiently on a large scale, and sources can be limited.

### BRIEF SUMMARY OF THE INVENTION

The present invention relates generally to solar energy techniques, and in particular to a method and a structure for a resulting solar module. By way of example, embodiments of the present invention have been applied to solar panels but it would be recognized the present invention can have a broader range of applicability.

Although orientation is not a part of the invention, it is convenient to recognize that a solar module has a side that faces the sun when the module is in use, and an opposite side that faces away from the sun. Although, the module can exist in any orientation, it is convenient to refer to an orientation where “upper” or “top” refer to the sun-facing side and “lower” or “bottom” refer to the opposite side. Thus an element that is said to overlie another element will be closer to the “upper” side than the element it overlies.

In a specific embodiment, a solar module includes a substrate member, a plurality of photovoltaic strips arranged in an array configuration overlying the substrate member, a concentrator structure overlying the photovoltaic strips, and preferably a coating on the concentrator structure. The photovoltaic strips extend generally in a longitudinal direction and are spaced from each other along a transverse direction. The photovoltaic strip center-to-center spacing is preferably greater than the transverse dimension of the strips, so that there are intervening substrate portions devoid of photovoltaic material.

The concentrator structure is formed with a plurality of elongated concentrator elements (sometimes referred to as lens elements) that extend along the longitudinal direction of the photovoltaic strips. For at least those embodiments where the concentrator elements lie in a common plane, their center-to-center spacing is nominally equal to that of the photovoltaic strips. Each concentrator element extends longitudinally along the direction of a given strip and transversely across the direction of the strips. A given concentrator element is formed so that parallel light incident on the top surface of the concentrator element, when it reaches the plane of the underlying photovoltaic strip, is confined to a region that has a transverse dimension that is smaller than that of the concentrator element, and possibly also smaller than that of the photovoltaic strip. In the illustrated embodiments, the concentration occurs at the upper surface, although it is also possible to have the concentration occur at the lower surface of the concentrator. Indeed, as in the case of normal lenses, it is possible to have both surfaces provide concentration.

It is common to refer to the concentrator element as providing magnification, since the photovoltaic strip, when viewed through the concentrator element, appears wider than it is. Put another way, when viewed through the concentrator element, the photovoltaic strip preferably fills the concentrator element aperture. Thus, from the point of view of incoming sunlight, the solar module appears to have photovoltaic material across its entire lateral extent. In representative embodiments, each of the elongated convex regions is configured to have a magnification ranging from about 1.5 to about 5. A coating material such as a self-cleaning coating overlies the plurality of elongated convex regions.

Although the term magnification is used, it is used in the sense of how much the light is concentrated, and so could equally be referred to as concentration. The magnification/concentration is also sometimes defined as the amount of photovoltaic material saved, and that number is typically less than the optical magnification/concentration since the photovoltaic strips will normally a slightly wider than the width of the light, especially to capture light incident at different angles. The term magnification will typically be used.

The portion of the surface of the concentrator element that provides the magnification has a cross section that can include one or more circular, elliptical, parabolic, or straight segments, or a combination of such shapes. Even though portions of the magnifying (typically upper) surface of the concentrator elements can be flat, it is convenient to think of, and refer to, the magnifying surface as convex, i.e., curved or arch-like. For embodiments where the cross section is semicircular, the surface of the magnifying portion of the concentrator element is semi-cylindrical. However, circular arcs subtending less than 180° are typically used. Although the convex surfaces were referred to as “annular” portions in the above-cited U.S. Patent Application No. 61/154,357, the “annular” nomenclature will not be used here. In some embodiments, the concentrator structure is extruded glass, although other fabrication techniques (e.g., molding) and other materials (e.g., polymers) can be used.

In an another embodiment, a solar module includes a concentrator structure formed at least in part from an extruded glass material and a plurality of photovoltaic strips arranged in an array configuration operably coupled to the concentrator structure. A plurality of elongated convex regions are configured within the concentrator structure. The plurality of elongated convex regions are respectively coupled to the plurality of photovoltaic strips in a specific embodiment. Each of the plurality of elongated convex regions includes a length and a convex surface region characterized by a radius of curvature. Each of the elongated convex regions is configured to have a magnification ranging from about 1.5 to about 5. A coating material overlies the plurality of elongated convex regions. A back cover member is covers the plurality of photovoltaic strips.

Many benefits can be achieved by ways of the present invention. For example, the present solar module provides a simplified structure for a manufacturing process. The solar module according to embodiments of the present invention eliminates the use of certain materials (e.g., acrylic) and reduces the amount of glass material for the concentrator structure. The present solar module may be fabricated using few process steps resulting in lower cost and improved product reliability due to less mismatch in thermal expansion coefficients of the materials.

A further understanding of the nature and advantages of the present invention may be realized by reference to the remaining portions of the specification and the drawings.

### BRIEF DESCRIPTION OF THE DRAWINGS

FIG. 1 is an exploded view of a solar module using conventional concentrating elements;

FIGS. 2A and 2B are cross-sectional and oblique views of a portion of a solar module according to an embodiment of the present invention;

FIG. 3 is a cross-sectional view of a portion of a solar module according to an alternative embodiment of the present invention;

FIGS. 4A, 4B, and 4C are optical schematics showing incoming sunlight at the summer solstice, at the equinoxes, and at the winter solstice for a solar module according to an embodiment of the present invention optimized for a tilt angle equal to the latitude; and

FIGS. 5A, 5B, and 5C optical schematics showing incoming sunlight at the summer solstice, at the equinoxes, and at the winter solstice for a solar module according to an embodiment of the present invention optimized for a tilt angle that differs from the latitude.

### DETAILED DESCRIPTION OF SPECIFIC EMBODIMENTS

Embodiments of the present invention provide structures and fabrication methods for a solar module, such as might be applied to solar panels. Embodiments of the present invention use concentrator elements to reduce the amount of photovoltaic material required, thereby reducing overall cost. It is noted that specific embodiments are shown for illustrative purposes, and represent examples. One skilled in the art would recognize other variations, modifications, and alternatives.

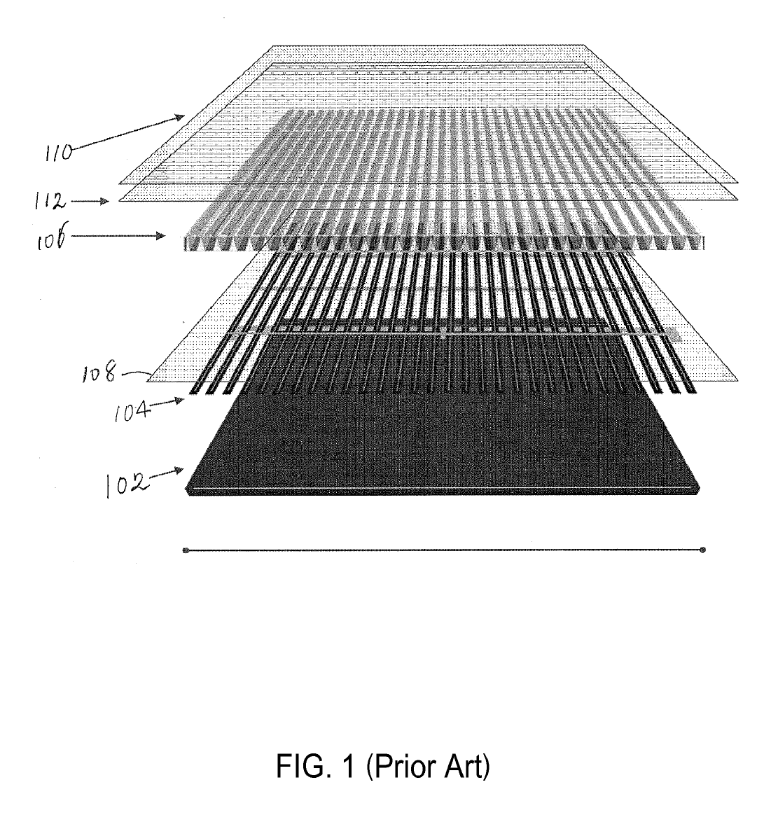

FIG. 1 is an exploded view of a conventional solar module 100. As shown, the conventional solar module includes, generally from back to front, the following elements: a back cover member 102; a plurality of photovoltaic strips 104 a plurality of elongate concentrator elements 106 aligned with and held to the photovoltaic strips by an an optically clear adhesive 108; and a cover member 110 attached to the concentrator lenses by an optically clear adhesive material 112. Back cover member 102 can be made of glass or a polymer material, and cover member 110 can be made of glass or a transparent polymer material. Concentrator lenses 106 can be glass or polymer, and as shown have a transverse cross section that is in the shape of an isosceles trapezoid, but other cross-sectional shapes are known, including those having one or more curved line segments.

This type of construction can be subject to some limitations. For example, the different materials are typically characterized by different thermal expansion coefficients, which can lead to mechanical stresses that reduce product reliability. Additionally, the concentrator lenses, when made of certain polymer material, such as acrylic, can deteriorate under the influence of the environment or solvents.

Representative Structures

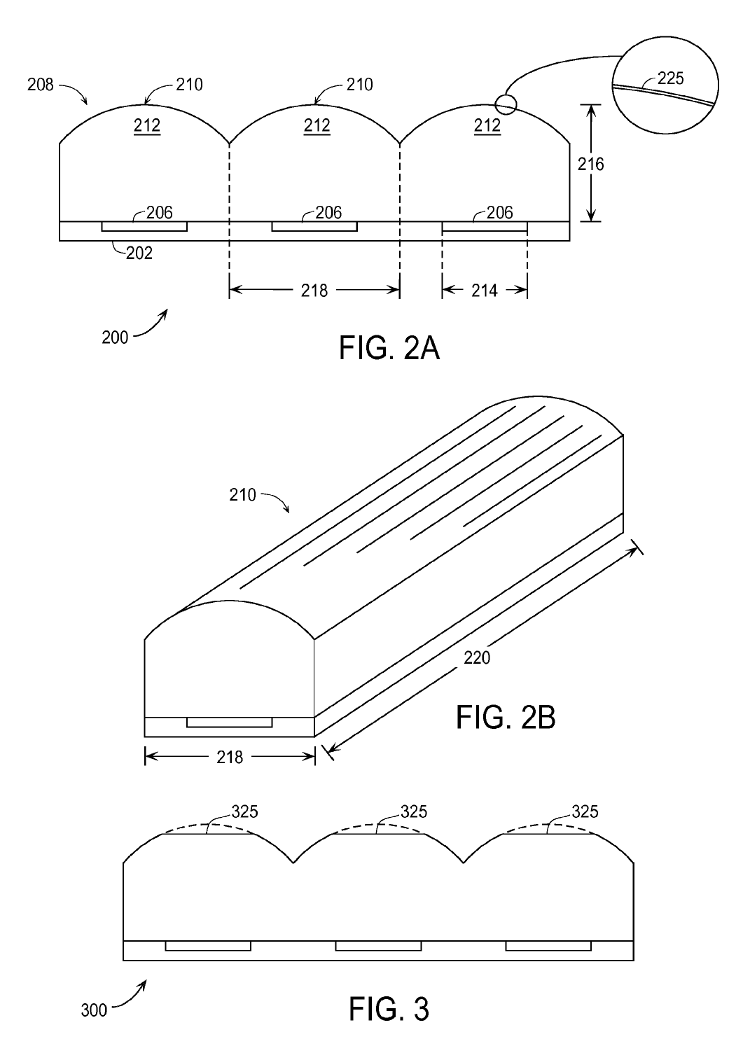

FIGS. 2A and 2B are cross-sectional and oblique views of a portion of a solar module 200 according to an embodiment of the present invention. A substrate member 202 supports a plurality of elongate photovoltaic regions 206. A concentrator lens structure 208 (sometimes referred to simply as the concentrator or the concentrator structure) overlies the photovoltaic regions, and includes a plurality of concentrator elements 210 aligned with the photovoltaic regions. In this embodiment, the photovoltaic regions are centered relative to the concentrator elements, but other embodiments described below have the photovoltaic regions offset relative to the concentrator elements.

The concentrator can be bonded to the photovoltaic strips using an optical elastomer, for example an ethylene vinyl acetate copolymer such as DuPont™ Elvax® EVA resin, and the like. In a specific embodiment, the photovoltaic strips are encapsulated in a polyvinyl fluoride (PVF) material such as DuPont™ Tedlar® polyvinyl fluoride. In a further specific embodiment, the module is formed by laminating the concentrator, an EVA film, the photovoltaic strips, and a PVF backsheet. The backsheet encapsulates the photovoltaic strips and associated wiring, and can be considered to define the substrate. A typical backsheet construction can include trilaminate where a polyester film is sandwiched between two layers of PVF. The laminated structure can then be mounted in a frame (not shown).

The cross section of a given concentrator element includes an upper portion 212 that is convex looking down, and a rectangular base portion below. As shown the upper portion of the cross section is a circular arc, but other shapes are possible. As mentioned above, the upper portion of the cross section can include one or more circular, elliptical, parabolic, or straight segments, or a combination of such shapes. The upper surface will sometimes be referred to as the convex surface.

As can be seen in FIG. 2A, and in the oblique view of FIG. 2B, which shows a single concentrator element 210 registered to its associated photovoltaic region, a given photovoltaic region is characterized by a width 214 while a given concentrator element is characterized by a height 216, a width 218 along a transverse direction, and a length 220 along a longitudinal direction. Since the concentrator elements are integrally formed as portions of the concentrator structure, the width corresponds to the transverse pitch of the photovoltaic regions, and similarly the pitch of the concentrator elements. Height 216 also corresponds to the thickness of the concentrator. If upper portion of the concentrator element cross section includes a circular arc, that portion is characterized by a radius of curvature.

Substrate member 202 can be made of glass, polymer, or any other suitable material. Photovoltaic regions 206 are preferably configured as strips, and can be silicon based, for example, monocrystalline silicon, polysilicon, or amorphous silicon material. Alternatively, the photovoltaic strip can be made of a thin film photovoltaic material. The thin film photovoltaic material may include CIS, CIGS, CdTe, and others. Each of the photovoltaic strips can have a width ranging from about 2 mm to about 10 mm, depending on the embodiment. In typical embodiments, the photovoltaic strips are cut from a wafer, but in other embodiments, the photovoltaic strips might be deposited on the substrate (although that might be more difficult).

The concentrator structure can be made of a glass material having a suitable optical property, e.g., a solar glass having a low iron concentration. Other glass materials such as quartz, fused silica, among others, may also be used. In some embodiments, the concentrator structure is made using an extrusion process so that the concentrator elements extend along the direction of the travel of the glass sheet. In other embodiments, the concentrator structure is made of a transparent polymer material such as acrylic, polycarbonate, and others, which may also be extruded. It may be desired in some embodiments to mold the concentrator structure.

The convex configuration of the upper portions of the concentrator elements provides a focusing effect whereby parallel light incident on the top surface of the concentrator element converges. Thus when the light reaches the plane of the underlying photovoltaic strip, it is confined to a region that has a transverse dimension that is smaller than that of the concentrator element, and possibly also smaller than that of the photovoltaic strip. The focusing property of the concentrator element can be characterized as a magnification. In specific embodiments, the magnification is in the range of 1.5 to about 5. Put another way, a photovoltaic strip, when viewed through the concentrator element appears about 1.5 to 5 times as wide.

As shown in FIGS. 2A and 2B, the upper surface of the concentrator elements intersects the transverse plane to define a circular arc subtending an angle that is less than 180°, although that is not necessary. The intersection of the arcs is typically rounded to provide a round-bottom notch. The magnification is defined at least in part by the height, width, and curvature. Increasing the magnification would tend to require increasing the thickness of the concentrator structure. This would require less photovoltaic material, but potentially result in greater losses in the concentrator material and a heavier module. One skilled in the art would recognize the tradeoffs that might be encountered. Additional details can be found in the above-referenced U.S. patent application Ser. No. 12/687,862.

As shown in the enlarged balloon of FIG. 2A, the concentrator structure is provided with a coating 225. The coating material can be selected to prevent dirt and other contaminants from building up on the surface. Saint-Gobain Glass markets what they refer to as “self-cleaning” glass, under the registered trademark SGG BIOCLEAN. An explanation on the Saint-Gobain Glass website describes the operation as follows:
A transparent coating on the outside of the glass harnesses the power of both sun and rain to efficiently remove dirt and grime. Exposure to the UV rays present in daylight triggers the decomposition of organic dirt and prevents mineral dirt from adhering to the surface of the glass. It also turns it “hydrophilic” meaning that when it rains the water sheets across the glass, without forming droplets, rinsing away the broken down dirty residues. Only a small amount of sunlight is required to activate the coating so the self-cleaning function will work even on cloudy days. A simple rinse of water during dry spells will help keep windows clean.
   U.S. Pat. No. 6,846,556 to Boire et al. titled “Substrate with a Photocatalytic Coating” describes such a glass. The K2 Glass division of K2 Conservatories Ltd. also manufactures and markets what they refer to as the Easy Clean System, namely “a system for converting ordinary glass into ‘Non Stick’, easy to clean glass.”

Wikipedia provides a number of suppliers of self-cleaning glass as follows (citations omitted):
The Pilkington Activ brand by Pilkington is claimed by the company to be the first self-cleaning glass. It uses the 15 nm thick transparent coating of microcrystalline titanium dioxide. The coating is applied by chemical vapor deposition
The SunClean brand by PPG Industries also uses a coating of titanium dioxide, applied by a patented process.
Neat Glass by Cardinal Glass Industries has a titanium dioxide layer less than 10 nm thick applied by magnetron sputtering
SGG Aquaclean (1st generation, hydrophilic only, 2002) and Bioclean (2nd generation, both photoactive and hydrophilic, 2003) by Saint-Gobain. The Bioclean coating is applied by chemical vapor deposition.

A coating, such as those described above, can be combined with other coatings to enhance the performance of the solar module. For example, anti-reflective coatings can be used to increase the amount of light captured by the solar module. XeroCoat, Inc. of Redwood City, Calif. and its subsidiary XeroCoat Pty. Ltd. of Brisbane, Australia state that they are working on a grant from Australia's Climate Ready program to address solar efficiency loss due to accumulated dust and soil, as well as reflection.

FIG. 3 is a cross-sectional view of a portion of a solar module 300 according to an alternative embodiment of the present invention. In this embodiment, the convex surface of the concentrator lens structure is modified to enable easy fabrication, especially for a glass material. As shown in a simplified diagram in FIG. 3, the convex surface of each of the concentrator elements has a central portion 325 that is flat, with curved portions on either side. A dashed line show what would otherwise be an uninterrupted curved surface. The “truncated” profile would normally be established during extrusion, and not by removing portions of an initially curved surface. Such a “truncated” configuration can be advantageous. For example, the thickness of the concentrator lens structure is effectively reduced, the amount of material used is reduced, and thus the final weight of the solar panel is also reduced. Additionally, the “truncated” configuration may be able to capture more diffuse light, further enhancing the performance of the solar panel.

### Fixed Tilt at Angle Equal to the Latitude

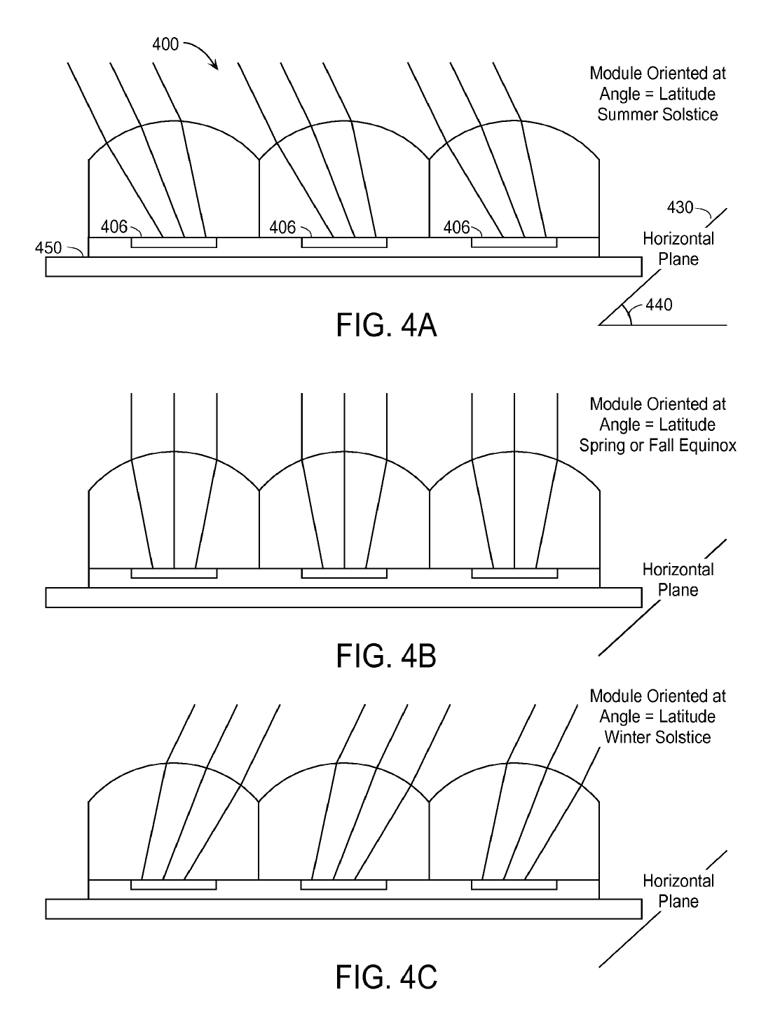

FIGS. 4A, 4B, and 4C optical schematics showing a fixed-tilt mounting configuration for a solar module 400 having photovoltaic strips 406 and concentrator elements 410. FIG. 4A shows the incoming sunlight at the summer solstice; FIG. 4B shows the incoming sunlight at the equinoxes; and FIG. 4C shows the incoming sunlight at the winter solstice.

The solar module can be similar to module 200 shown in FIGS. 2A and 2B. The module has each of photovoltaic strips 406 disposed at a center of its respective concentrator element 410. For convenience, the horizontal plane, designated 430, is shown tilted with respect to the figure by an angle, designated 440, equal to the latitude so that the module is shown horizontal in the figure. In the real world, the module would be tilted away from the horizontal by a tilt angle equal to the latitude. A mounting structure 450 is shown schematically, but the particular mounting brackets or other details are not shown, and can follow any standard acceptable design. For mounting to a sloped roof that has a different tilt angle than the latitude, it may be desirable to use a mounting structure having a tilt angle between that of the module and that of the roof. For a situation where the roof's tilt angle is equal to the latitude, mounting structure could be the roof itself.

As is known, the yearly variation of the sun's maximum angle from the horizontal plane is 47° (twice Earth's tilt 23.5°), with the value at either of the equinoxes being given by 90° minus the latitude. Thus, for example, at 50° N, the sun's maximum angle from the horizontal would be 63.5° at the June solstice, 40° at either equinox, and 16.5° at the December solstice. Similarly, at the equator, the maximum angle from the horizontal would be 66.5° above the northern end of the horizon at the June solstice, 90° (i.e., directly overhead) at either equinox, and 66.5° above the southern end of the horizon at the December solstice (i.e., varying between the extremes of ±23.5° from overhead).

As can be seen, tilting the module to an angle matching the latitude maximizes the overall efficiency, with all the direct sunlight being captured by the solar module throughout the year. The sun hits the module at normal incidence at the equinoxes, and at ±23.5° to normal at the solstices. Thus, having the photovoltaic strips centered relative to the concentrator elements is optimum. It is not, however, always possible to tilt the module to match the latitude, and described below is a module configuration for a tilt angle that differs from the latitude.

Fixed Tilt at Angle that Differs from the Latitude

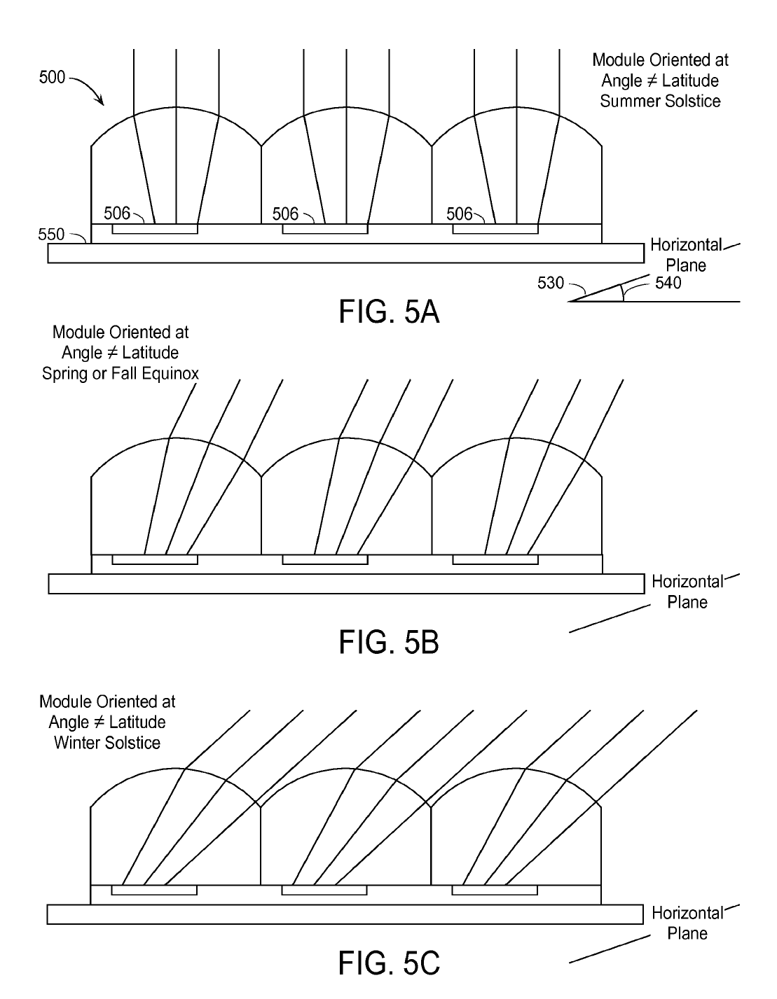

FIGS. 5A, 5B, and 5C are optical schematics showing a fixed-tilt mounting configuration for a solar module 500 having photovoltaic strips 506 and concentrator elements 510. FIG. 5A shows the incoming sunlight at the summer solstice; FIG. 5B shows the incoming sunlight at the equinoxes; and FIG. 5C shows the incoming sunlight at the winter solstice. As in the case of FIGS. 4A-4C, the horizontal plane, designated 530, is shown tilted with respect to the figure by an angle, designated 540, so that the module is shown horizontal in the figure.

In this embodiment, the tilt angle differs from the latitude. The solar module can be similar to module 200 shown in FIGS. 2A and 2B, except that photovoltaic strips 506 are offset from the centers of concentrator elements 510 to maximize the solar collection over the year. Using a tilt angle that differs from the latitude is often dictated by a desire to mount the panel directly to an existing roof whose tilt angle is already established. The roof is shown schematically with a reference numeral 550. The particular mounting brackets or other structures are not shown, and can follow any standard acceptable design for mounting solar panels on sloped roofs.

Although it may be possible to plan a building to have its roof sloped at an optimum angle for the building's latitude, it should be recognized that other constraints can dictate the roof slope. It is also possible to mount the solar module at a desired tilt angle relative to the roof, which can be the case for the embodiment described above with the tilt angle being equal to the latitude. The direct mounting can have the benefits of relative simplicity and sturdiness, which is especially advantageous in a windy situation.

Consider a specific example of a roof tilt of 20° and a latitude of 45° N. For that latitude, the sun's maximum angle from the horizontal varies from 21.5° to 68.5° between the December solstice and the June solstice, with an angle of 45° at the equinoxes. What this means is that the angle of incidence, measured from a normal to the horizontal plane varies from 21.5° in June to 68.5° in December. Assuming proper direction of the roof having the 20° tilt, the maximum angle of incidence from the normal to the roof would vary between 1.5° in June and 48.5° in December.

In this example, tilting the solar module by 20° toward the sun has resulted in improving the relative orientation, with the sun being almost normally incident (88.5° from the plane of the module or 1.5° from the normal to the module) in June. The sun's angle relative to the module in December is better than without the tilt, but over the course of the year, the sun will always be off to one side of the normal. Offsetting the photovoltaic strips relative to the concentrator elements makes the capture of the incident radiation more efficient. For this example where the latitude is greater than the tilt angle, the photovoltaic strips are offset in the uphill direction; if the tilt angle exceeded the latitude, the offset would be in the downhill direction.

### Method of Manufacture

In a specific embodiment, a method of fabricating a solar module according includes providing a substrate member, including a surface region, providing a plurality of photovoltaic strips are provided overlying the surface region of he substrate, providing a concentrator lens structure. The substrate member can be a glass material, a polymer material among others. The photovoltaic strips can be provided using a pick and place process and may be arranged in an array configuration. In a specific embodiment, a suitable adhesive material is used.

In a specific embodiment, the concentrator lens structure can be made of a glass material or an optically transparent polymer material. Preferably the glass material is a solar glass having a low iron concentration. In a specific embodiment, a plurality of elongated convex regions are configured within the concentrator structure. Each of the plurality of elongated convex regions is configured to provide a magnification of about 1.5 to about 5. Depending on the embodiment, the plurality of photovoltaic strips can be formed using techniques such as a singulation process or a dicing process. Each of the plurality of photovoltaic strip can have a width ranging from 1.5 mm to about 10 mm depending on the application.

In a specific embodiment, the method includes coupling the plurality of elongated convex region to each of the respective photovoltaic using an optically clear adhesive such as EVA or an UV curable material. The solar module may be inserted into a frame member to further protect edges of the solar module and provide rigidity for the solar panel. Of course, there can be other modifications, variations, and alternatives.

While the above is a complete description of specific embodiments of the invention, the above description should not be taken as limiting the scope of the invention as defined by the claims.

What is claimed is:

1. A solar module comprising:
a substrate member;
a plurality of photovoltaic strips arranged in an array configuration overlying the substrate member;
a concentrator structure comprising extruded glass material operably coupled to the plurality of photovoltaic strips;
a plurality of elongated convex regions configured within the concentrator structure, the plurality of elongated convex regions being respectively coupled to the plurality of photovoltaic strips, each of the plurality of elongated convex regions being characterized by a length and having a convex surface region, each of the elongated convex regions being configured to have a magnification ranging from about 1.5 to about 5; and
a coating material overlying the plurality of elongated convex regions.

2. The module of claim 1 wherein the photovoltaic strips are laterally centered with respect the elongated convex regions.

3. The module of claim 1 wherein the photovoltaic strips are laterally offset from the centers of the elongated convex regions but.

4. The module of claim 1 wherein the convex surface region is semi-circular in shape.

5. The module of claim 1 wherein the convex surface region is a truncated semi-circular shape having a flat top region.

6. The module of claim 1 wherein the extruded glass material is characterized by a low iron content.

7. The module of claim 1 wherein the extruded glass material comprises a solar glass.

8. The module of claim 1 wherein the concentrator structure has a length of greater than about 156 mm and a width greater than about 156 mm.

9. The module of claim 1 wherein the concentrator structure has a length of greater than about 1000 mm and a width greater than about 1700 mm.

10. The module of claim 1 wherein the coating material is similar and/or equivalent to Bioclean cool-lite St glass, a dual coated self-cleaning glass manufactured by SanGobian Glass or Celsius Plus Performance glass with a standard Easy Clean System from K2 Glass Ltd, or similar.

11. The module of claim 1 wherein the substrate member is selected from a glass substrate and a polymer substrate.

12. The module of claim 1 wherein the magnification is 1.5 or greater.

13. The module of claim 1 wherein the magnification is 5 or greater.

14. The module of claim 1 wherein each of the photovoltaic strips is selected from a silicon bearing material, a CIGS/CIS, a CdTe, GaAs based material, or a Ge based material.

15. The module of claim 1 wherein the solar module is mounted on a building structure.

16. The module of claim 1 wherein the solar module is mounted on a tracker system.

17. The module of claim 1 wherein one or more of the photovoltaic strips is operably coupled in an offset configuration to respective one or more elongated convex regions.

18. The module of claim 1 wherein each of the plurality of photovoltaic strips has a width of 1.5 mm to about 12 mm and a length of about 156 mm to about 1000 mm.

19. The module of claim 1 wherein each of the plurality of convex regions includes a truncated aperture region.

20. The module of claim 1 further comprises a frame member provided to protect the solar module.

21. A solar module comprising:
a concentrator structure, the concentrator structure comprising an extruded glass material,
a plurality of photovoltaic strips arranged in an array configuration operably coupled to the concentrator structure;
a plurality of elongated convex regions configured within the concentrator structure, the plurality of elongated convex regions being respectively coupled to the plurality of photovoltaic strips, each of the plurality of elongated convex regions being characterized by a length and having a convex surface region, each of the elongated convex regions being configured to have a magnification ranging from about 1.5 to about 5;
a coating material overlying the plurality of elongated convex regions; and
a back cover member disposed to enclose the plurality of photovoltaic strips.

22. A method of fabricating a solar module, the method comprising:
providing a concentrator structure comprising an extruded glass material, the concentrator structure including a plurality of elongated convex regions, each of the plurality of elongated convex regions comprising a length and a convex surface region characterized by a radius of curvature, each of the elongated convex region being configured to have a magnification ranging from about 1.5 to about 5;
providing a plurality of photovoltaic strips, each of the plurality of photovoltaic strip being formed using a singulation and/or a dicing process, each of the plurality of photovoltaic strips including a front surface region and a back surface region; and
coupling the front surface of each of the plurality of photovoltaic strips to the respective elongated convex region of the concentrator structure.

23. The method of claim 22 wherein the coupling step uses a pick and place process.

24. The method of claim 22 wherein the coupling step uses a pick and place process.

25. A method of fabricating a solar module, the method comprising:
providing a substrate member including a first surface region;
providing a plurality of photovoltaic strips overlying the first surface region of the substrate member, each of the plurality of photovoltaic strip being formed using a singulation and/or a dicing process, each of the plurality of photovoltaic strips including a front surface region and a back surface region;
providing a concentrator structure comprising an extruded glass material, the concentrator structure including a plurality of elongated convex regions, each of the plurality of elongated convex regions being characterized by a length and having a convex surface region characterized by a radius of curvature, each of the elongated convex region being configured to have a magnification ranging from about 1.5 to about 5; and
coupling the front surface of each of the plurality of photovoltaic strips to the respective elongated convex region of the concentrator structure.
